(19) United States
(12) Patent Application Publication
(10) Pub. No.: US 2017/0038529 A1
(43) Pub. Date: Feb. 9, 2017

(54) OPTICAL WAVEGUIDE ELEMENT AND METHOD FOR MANUFACTURING OPTICAL WAVEGUIDE ELEMENT

(71) Applicant: NEC CORPORATION

(72) Inventor: Morio TAKAHASHI, Tokyo (JP)

(73) Assignee: NEC CORPORATION, Minato-ku, Tokyo (JP)

(21) Appl. No.: 15/101,022

(22) PCT Filed: Dec. 12, 2014
(86) PCT No.: PCT/JP2014/006211

§ 371 Date: Jun. 2, 2016

(30) Foreign Application Priority Data
Dec. 25, 2013 (JP) 2013-267193

(51) Int. Cl. G02B 6/122; H01S 5/068; G02B 6/134; H01S 5/10; G02B 6/126; G02B 6/136

(52) U.S. Cl. CPC G02B 6/122; G02B 6/126; G02B 6/136; G02B 6/134; H01S 5/1071; H01S 5/068; G02B 2006/12061

(57) ABSTRACT

There is provided an optical waveguide element and a method for manufacturing an optical waveguide element that make it possible, while reducing the cost of manufacturing the optical waveguide element, to reliably eliminate stray light that affects primary signal light.

The optical waveguide element of the present invention includes a silicon layer and silicon-dioxide layers placed above and below the silicon layer, in which the silicon layer includes a ridge optical waveguide and an impurity-implanted region placed at not less than a predetermined distance from the ridge optical waveguide.

### TECHNICAL FIELD

The present invention relates to an optical waveguide element and a method for manufacturing an optical waveguide element.

### BACKGROUND ART

Larger-capacity and longer-distance optical fiber communication technology has greatly progressed due to high-speed intensity modulation signals and wavelength multiplexing. In addition, in recent years, the improvement of digital signal processing technology has enabled transmission capacities in existing optical fiber networks to be drastically increased using polarized light multiplexing and multi-level phase modulation technology.

The drastic increases in the transmission capacities have caused the higher functions, higher precision, and smaller sizes of optical waveguide elements to be demanded. For example, a small-sized optical waveguide element is disclosed in PTL 1. However, the reduction of the costs of optical waveguide elements has also been demanded. To meet such contradictory demands, a number of technological developments have been made for actualizing silicon optical waveguides which can be drastically downsized in comparison with conventional glass waveguides. Such a silicon optical waveguide can be actualized utilizing complementary metal oxide semiconductor (CMOS) process technology used in manufacture of large scale integration (LSI) (see NPL 1).

However, an optical fiber for communication formed of glass and a silicon optical waveguide element formed of silicon have greatly different sizes in propagation modes. Therefore, optical coupling between such an optical fiber for communication and such a silicon optical waveguide element is difficult. The design of a silicon optical waveguide circuit in a strong optical confinement state is also difficult, and has a number of problems in the loss and properties of propagating light, and the like.

Among such silicon optical waveguides, a ridge silicon optical waveguide is favorable as a silicon optical waveguide because the ridge silicon optical waveguide can be downsized, the loss of coupling between the ridge silicon optical waveguide and an optical fiber for communication can be improved, and the properties of propagating light in the ridge silicon optical waveguide are practicable.

PTL 2 discloses an optical switch including a ridge silicon optical waveguide. The optical switch according to PTL 2 includes: an optical waveguide through which light propagates; and a light absorber including a material of which the energy band width is less than that of a semiconductor included in the optical waveguide. The light absorber absorbs light leaking in a portion other than the optical waveguide, and prevents the leaking light from flowing into the optical waveguide. PTL 2 discloses that InGaAs or the like is used in the light absorber when the optical waveguide includes InP, and that an organic film, a resin, or the like containing a metal such as chromium, or the filler (powder) of the metal is used in the light absorber when the optical waveguide includes a material such as glass or lithium niobate.

### CITATION LIST

### Patent Literature

[PTL 1] Japanese Patent Laid-Open No. 8-313745
[PTL 2] Japanese Patent Laid-Open No. 2004-264631

### Non Patent Literature

[NPL 1] R. A. Soref and J. P. Lorenzo “All-silicon active and passive guided-wave components for 1.3 and 1.6 μm”, Journal of Quantum Electronics, Vol. QE-22, No. 6, p. 873 (1986)

### SUMMARY OF INVENTION

### Technical Problem

As described above, in PTL 2, the material of which the energy band width is less than that of the semiconductor included in the optical waveguide is used as the light absorber, and the light absorber absorbs light leaking from the optical waveguide. However, the light absorber that absorbs light due to the difference between the energy band widths may emit new light when absorbing light. In other words, in the optical switch according to PTL 2, the light absorber may emit new light after absorbing light leaking from the optical waveguide, and the new light may become stray light. As described above, the optical switch according to PTL 2 has a problem that stray light is insufficiently eliminated.

Further, in the optical switch according to PTL 2, a light absorber of which the material is different from that of an optical waveguide layer is formed in the optical waveguide layer. Therefore, the manufacture of the optical switch requires the placement of light absorbers formed of different materials on the top, bottom, right, and left of the optical waveguide in the optical waveguide layer, thereby increasing the number of processes such as resist patterning, etching, and resist stripping in CMOS process technology. Accordingly, the optical switch according to PTL 2 has a problem that the cost needed for manufacturing the optical switch is increased.

An object of the present invention is to solve the problems described above, and to provide an optical waveguide element and a method for manufacturing an optical waveguide element that make it possible, while reducing the cost of manufacturing the optical waveguide element, to reliably eliminate stray light that affects primary signal light.

### Solution to Problem

An optical waveguide element of the present invention includes a silicon layer and silicon-dioxide layers placed above and below the silicon layer, wherein the silicon layer comprises a ridge optical waveguide and an impurity-implanted region placed at not less than a predetermined distance from the ridge optical waveguide.

A method for manufacturing an optical waveguide element of the present invention includes: protecting, with a first resist, a top surface of a region other than a region into which an impurity is implanted, in a silicon layer; implanting an impurity that forms an electron or a hole into the silicon layer from above a top surface of the silicon layer protected with the first resist; stripping the first resist after implanting the impurity; protecting, with a second resist, a region corresponding to a top surface of a ridge optical waveguide in the silicon layer after stripping the first resist; removing a portion having a predetermined depth from the top surface of the silicon layer in a region other than the region protected with the second resist in the silicon layer protected with the second resist; and stripping the second resist after removing the portion having the predetermined depth.

Another method for manufacturing an optical waveguide element of the present invention includes: placing a silicon layer on a top surface of a silicon-dioxide layer; placing a second resist on a region corresponding to a top surface of a projection including a ridge optical waveguide in the silicon layer; subjecting a predetermined region including the second resist of the silicon layer to etching; stripping the second resist after the etching; placing a first resist on a top surface of a region other than a region into which an impurity is implanted in the silicon layer after stripping the second resist; implanting an impurity that forms an electron or a hole from above the first resist and the silicon layer; stripping the first resist after implanting the impurity; and placing another silicon-dioxide layer on a top surface of a silicon layer from which the first resist is stripped.

### Advantageous Effects of Invention

According to the optical waveguide element of the present invention, it is possible to reliably eliminate stray light that affects primary signal light while reducing the cost of manufacturing the optical waveguide element.

### BRIEF DESCRIPTION OF DRAWINGS

FIG. 1 is a cross-sectional view of an optical waveguide element 1 according to a first exemplary embodiment of the present invention.

FIG. 2 is a cross-sectional view of an optical waveguide element 1 according to a second exemplary embodiment of the present invention.

FIG. 3 is a flowchart representing the procedure of manufacturing the optical waveguide element 1 according to the second exemplary embodiment of the present invention.

FIG. 4 is a cross-sectional view of an SOI wafer 201 in S101 in the course of manufacturing the SOI wafer 201 according to the second exemplary embodiment of the present invention.

FIG. 5 is a cross-sectional view of the SOI wafer 201 in S103 in the course of manufacturing the SOI wafer 201 according to the second exemplary embodiment of the present invention.

FIG. 6 is a cross-sectional view of the SOI wafer 201 in S105 in the course of manufacturing the SOI wafer 201 according to the second exemplary embodiment of the present invention.

FIG. 7 is a cross-sectional view of the SOI wafer 201 in S106 in the course of manufacturing the SOI wafer 201 according to the second exemplary embodiment of the present invention.

FIG. 8 is a cross-sectional view of the SOI wafer 201 in S107 in the course of manufacturing the SOI wafer 201 according to the second exemplary embodiment of the present invention.

FIG. 9 is a cross-sectional view of the SOI wafer 201 formed by the manufacturing procedure of the second exemplary embodiment of the present invention.

FIG. 10 is a flowchart representing the other procedure of manufacturing the optical waveguide element 1 according to the second exemplary embodiment of the present invention.

FIG. 11 is a cross-sectional view of the SOI wafer 201 in S202 in the other course of manufacturing the SOI wafer 201 according to the second exemplary embodiment of the present invention.

FIG. 12 is a cross-sectional view of the SOI wafer 201 in S203 in the other course of manufacturing the SOI wafer 201 according to the second exemplary embodiment of the present invention.

FIG. 13 is a cross-sectional view of the SOI wafer 201 in S206 in the other course of manufacturing the SOI wafer 201 according to the second exemplary embodiment of the present invention.

FIG. 14 is a cross-sectional view of the SOI wafer 201 in S208 in the other course of manufacturing the SOI wafer 201 according to the second exemplary embodiment of the present invention.

FIG. 15 is a cross-sectional view of an SOI wafer 201 according to a third exemplary embodiment of the present invention.

FIG. 16 is a cross-sectional view of an SOI wafer 201 according to a fourth exemplary embodiment of the present invention.

FIG. 17 is a block configuration diagram of an optical receiver using a digital coherent system according to a fifth exemplary embodiment of the present invention.

FIG. 18 is a view illustrating a configuration example of a 90-degree hybrid mixer 302 according to the fifth exemplary embodiment of the present invention.

FIG. 19 is a view illustrating a configuration example of a polarization beam splitter 301 according to a sixth exemplary embodiment of the present invention.

FIG. 20 illustrates a configuration example of a tunable laser 400 utilizing a ring resonator according to a seventh exemplary embodiment of the present invention.

### DESCRIPTION OF EMBODIMENTS

### First Exemplary Embodiment

A first exemplary embodiment of the present invention will be described with reference to the drawings.

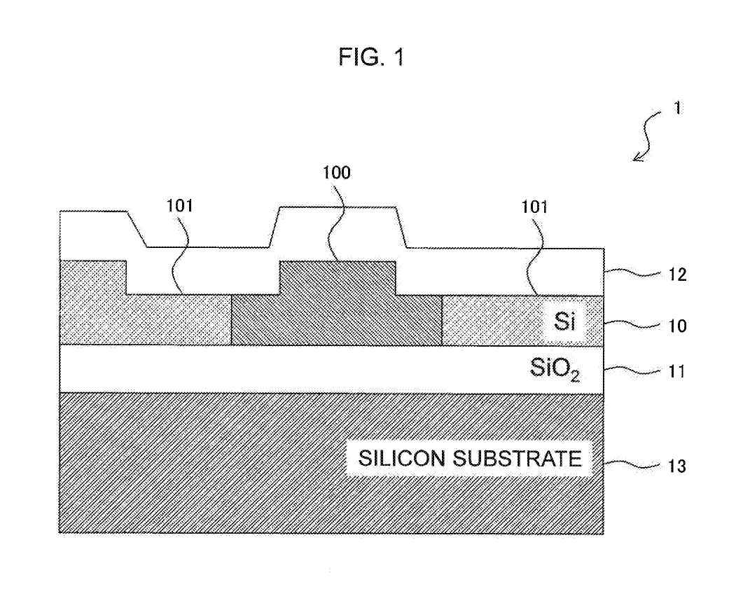

FIG. 1 is a cross-sectional view of an optical waveguide element 1 according to the first exemplary embodiment of the present invention. As illustrated in FIG. 1, the optical waveguide element 1 includes a Si layer 10, SiO₂ layers 11 and 12, and a silicon substrate 13. As illustrated in FIG. 1, the Si layer 10 of the optical waveguide element 1 includes a ridge optical waveguide in the first exemplary embodiment of the present invention.

The SiO₂ layers 11 and 12 are disposed above and below the Si layer 10 as illustrated in FIG. 1. The SiO₂ layers 11 and 12 confine propagating light in the Si layer 10 because the refractive index of SiO₂ is less than that of Si.

The Si layer 10 includes a projection shape (includes a ridge optical waveguide) as illustrated in FIG. 1, and light is confined in such a projection and propagates. Hereinafter, a region through which light propagates is described as an optical waveguide 102.

In the optical waveguide element 1, the Si layer 10 further includes an impurity-implanted region 101 in which an impurity is implanted into a predetermined region. As illustrated in FIG. 1, the impurity-implanted region 101 of the Si layer 10 is disposed at not less than a predetermined distance from the projection in the Si layer 10. Hereinafter, the projection, and a flat portion which is disposed between the projection and the impurity-implanted region 101 and into which no impurity is implanted are described as a core region 100.

The impurity-implanted region 101 has a light absorption coefficient increased in comparison with the core region 100, and therefore also has a varying optical refraction index according to the Kramers-Kronig relation. In other words, optical reflection may occur because a difference in refractive index occurs in the boundary between the core region 100 and the impurity-implanted region 101 in the Si layer 10.

Accordingly, it is also possible that radiated light generated from primary signal light propagating through the optical waveguide of the core region 100 is reflected off the boundary. When the boundary exists near the optical waveguide 102 of the core region 100, reflected light returns to the optical waveguide 102, interferes with primary signal light, and degrades the properties of the primary signal light.

Thus, in the optical waveguide element 1 of the first exemplary embodiment of the present invention, reflected light is prevented from interfering with primary signal light by disposing the impurity-implanted region 101 of the Si layer 10 in a region at not less than a predetermined distance from the projection to separate the boundary at not less than a predetermined distance from the projection.

The impurity-implanted region 101 is disposed, for example, in a region at a distance of 0.5 μm or more from a side of the projection to reduce the influence of generated reflected light on primary signal light.

The impurity-implanted region 101 eliminates stray light propagating through any place other than the core region 100. The impurity-implanted region 101 is formed by implanting, into the Si layer 10, an impurity that forms electrons or holes in the Si layer 10, and attenuates light by free carrier absorption. The impurity is, for example, phosphorus or boron. When phosphorus is the impurity, electrons are formed in the Si layer 10. When boron is the impurity, holes are formed in the Si layer 10.

In the first exemplary embodiment of the present invention, the impurity is introduced into the predetermined region of the Si layer 10 by a method with ion implantation or by a method with high-temperature diffusion. In the method with the ion implantation, the impurity is introduced into the predetermined region of the Si layer 10 by implanting, under high vacuum, an ion beam accelerated by a magnetic field into a wafer in which any place other than a region into which the impurity is intended to be implanted is masked. In the method with the high-temperature diffusion, a wafer in which any place other than a region that is intended to be subjected to diffusion is masked is introduced into a high-temperature furnace, and the impurity is diffused from an unmasked wafer surface to introduce the impurity into the predetermined region of the Si layer 10.

In the Si layer 10 including the impurity-implanted region 101, light (stray light) propagating through any place other than the core region can be attenuated by the impurity-implanted region 101.

As described above, the optical waveguide element 1 of the first exemplary embodiment of the present invention includes the impurity-implanted region 101 in which the impurity is implanted into the predetermined region of the Si layer 10, and can therefore attenuate light (stray light) propagating through any place other than the core region 100 of the Si layer 10 by free carrier absorption. Unlike the light absorber which absorbs light due to a difference in energy band width, described in PTL 2, it is possible to reliably eliminate stray light because it is less likely to emit new light when light is absorbed.

In the optical waveguide element 1 of the first exemplary embodiment of the present invention, the impurity-implanted region 101 is formed in the Si layer 10 by directly implanting the impurity into the Si layer 10. Accordingly, a cost needed for manufacturing the optical waveguide element 1 can be reduced because it is not necessary to form, in the optical waveguide layer, a light absorber of which the material is different from that of an optical waveguide layer, as described in PTL 2.

### Second Exemplary Embodiment

A second exemplary embodiment of the present invention will be described with reference to the drawings.

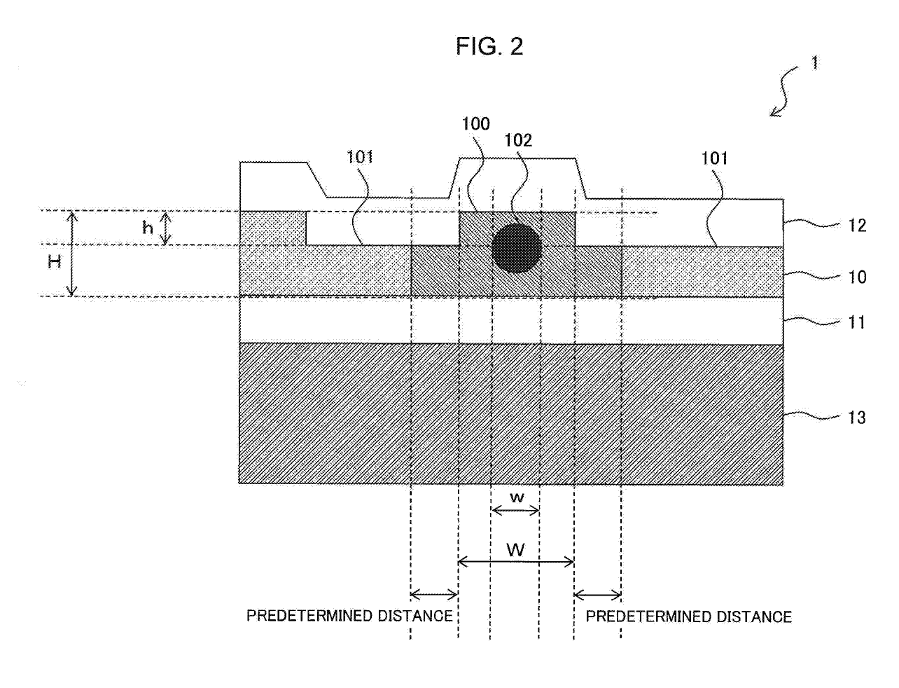

FIG. 2 is a cross-sectional view of an optical waveguide element 1 according to the second exemplary embodiment of the present invention. Like the optical waveguide element 1 according to the first exemplary embodiment, a Si layer 10 in the optical waveguide element 1 of the second exemplary embodiment of the present invention also includes a ridge optical waveguide as illustrated in FIG. 2.

The Si layer 10 includes a core region 100 (includes the ridge optical waveguide) including a projection and a flat portion into which no impurity is implanted, as illustrated in FIG. 2, and light is confined in the core region 100, and propagates. A light propagation mode is determined depending on the size (width W, height H, and level difference h in FIG. 2) of the projection. The propagation mode is confined in a predetermined region (optical waveguide 102) of the core region 100 in FIG. 2, and light exists in a width (width w in FIG. 2) depending on a confinement state.

When the Si layer 10 has a projection shape having a width W of 1.2 μm, a height H of 1.5 μm, and a level difference h of 0.5 μm, the optical waveguide 102 acts as a single mode waveguide including one propagation mode. In the example (width W of 1.2 μm, height H of 1.5 μm, and level difference h of 0.5 μm) of the size of the projection described above, the width w of a range in which light exists is 6 μm or less even when including a safety distance.

In the optical waveguide element 1 of the present invention, an impurity-implanted region 101 is disposed in a region in which unnecessary silicon remains in the Si layer 10, and the intensity of light propagating through a slab waveguide is attenuated by free carrier absorption.

A dry etching apparatus using plasma and etching gas is used in the course of manufacturing the optical waveguide element 1. The dry etching apparatus may cause an etching area to be locally large or to be otherwise locally small depending on the placement design of an optical waveguide. In such a case, an etching rate distribution in a wafer surface in which the optical waveguide 102 is formed, and the etching rate of the whole wafer change, and it is difficult to form the optical waveguide with high precision.

Thus, an etching area is reduced, and the stabilization of a distribution in an etching surface, and of an etching rate is attempted by etching only the vicinity of the core region 100.

However, silicon remains in an unetched region (residual silicon region) in the Si layer 10 included in the wafer. Because the Si layer 10 is put between SiO₂ layers 11 and 12, light is confined in the residual silicon region. Hereinafter, a residual silicon region through which light propagates is described as a slab region. In other words, in the Si layer 10, the slab region other than the core region 100 including the optical waveguide includes a slab waveguide through which light propagates.

When light exists in the slab waveguide, the light is confined in the slab waveguide, propagates, and spreads over the whole optical waveguide element with being hardly attenuated. When light propagating through the slab waveguide has the same wavelength as primary signal light propagating through the optical waveguide 102, the light propagating through the slab waveguide interferes with the primary signal light, thereby changing the phase and intensity of the primary signal light, in the core region 100 of the optical waveguide. As a result, the quality of the primary signal light is degraded.

Light propagating through the slab waveguide is generated primarily when optical coupling from an optical fiber to a silicon optical waveguide element occurs. Uncoupled light corresponding to a coupling loss is generated in the optical coupling, propagates through the slab waveguide, and spreads over the whole silicon optical waveguide element. Light propagating through the slab waveguide is generated in the event of a loss relating to filter properties in an optical waveguide circuit. With regard to the loss relating to the filter properties, light (radiated light) radiated outside the core region 100 is generated as a loss, for example, in a branch circuit or the like, propagates through the slab waveguide, and spreads over the whole silicon optical waveguide element.

Alternatively, use of design, e.g., in which the slab region (residual silicon region other than core region 100) is removed from the Si layer 10, in the optical waveguide element 1 requires additional processes such as resist patterning, etching, and resist stripping, and results in an increased manufacturing cost.

Thus, in the optical waveguide element 1 according to the second exemplary embodiment, an impurity is implanted into the slab region unnecessary in the Si layer 10, and the intensity of light propagating through the slab waveguide is attenuated by free carrier absorption. The impurity is implanted into the region other than the core region 100 in the Si layer 10. Hereinafter, the region into which the impurity is implanted is described as the impurity-implanted region 101. The impurity-implanted region 101 is disposed in the region between the core region 100 and another core region 100, and readily attenuates light propagating through the slab waveguide (slab-propagating light). Accordingly, even when slab-propagating light is generated, the slab-propagating light does not affect primary signal light.

Light attenuation due to an impurity is known as free carrier absorption. The rate of the attenuation of propagating light is increased with increasing the amount of an implanted impurity. When the wavelength of propagating light is 1.3 μm, a propagation loss of about 11 dB/cm is caused in a case in which the concentration of an impurity that generates electrons is 10¹⁸ cm⁻³, and a propagation loss of about 130 dB/cm is caused in a case in which the concentration is 10¹⁹ cm⁻³. Accordingly, most of slab-propagating light can be eliminated when the concentration of the impurity is 10¹⁹ cm⁻³.

Electrons or holes are formed in the impurity-implanted region 101 by the implanted impurity (phosphorus or boron). When an optical signal propagates through the impurity-implanted region 101, free carrier absorption occurs, and the optical signal attenuates. The free carrier absorption results in generation of only heat and in emission of no new light even when light is absorbed. Accordingly, the impurity-inflow region 101 according to the second exemplary embodiment can reliably eliminate stray light.

Methods for introducing the impurity into the predetermined region of the Si layer 10 are a method with high-temperature diffusion, and a method with ion implantation.

In the method with the high-temperature diffusion, a wafer in which any place other than a region that is intended to be subjected to the diffusion is masked is introduced into a high-temperature furnace, and the impurity is diffused from an unmasked wafer surface to introduce the impurity into the predetermined region of the Si layer 10. In the method with the high-temperature diffusion, a certain high temperature, of desirably 1000 degrees or more, is required, and a hard mask of SiO₂ or the like is required.

In the method with the ion implantation, an ion beam accelerated by a magnetic field is implanted, under high vacuum, into a wafer in which any place other than a region into which the impurity is intended to be implanted is masked, and the impurity is introduced into the predetermined region of the Si layer 10. The amount of the implanted impurity can be accurately controlled by an ion current. An implantation depth can also be accurately controlled by an acceleration voltage. Accordingly, in the method with the ion implantation, a desired amount of the impurity can be accurately introduced into a desired position in the Si layer 10.

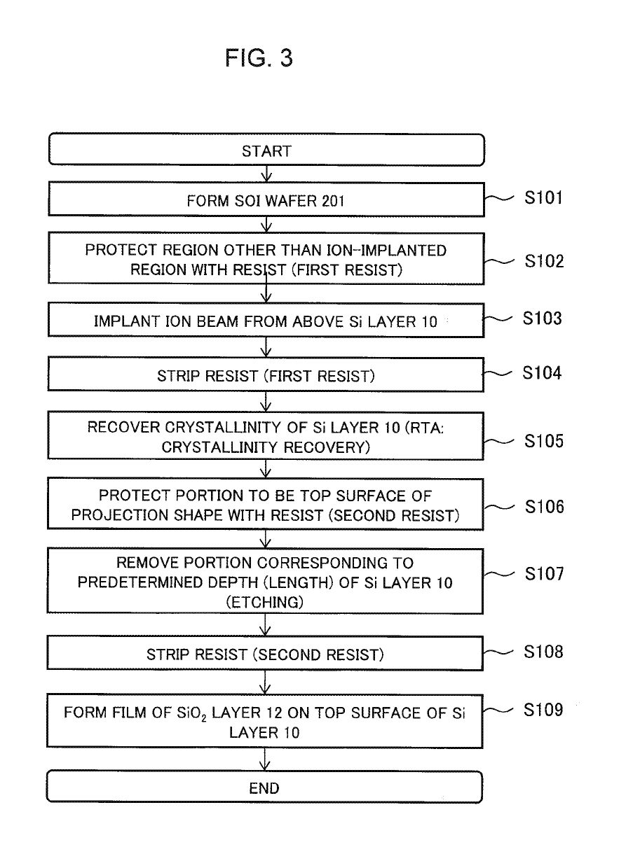

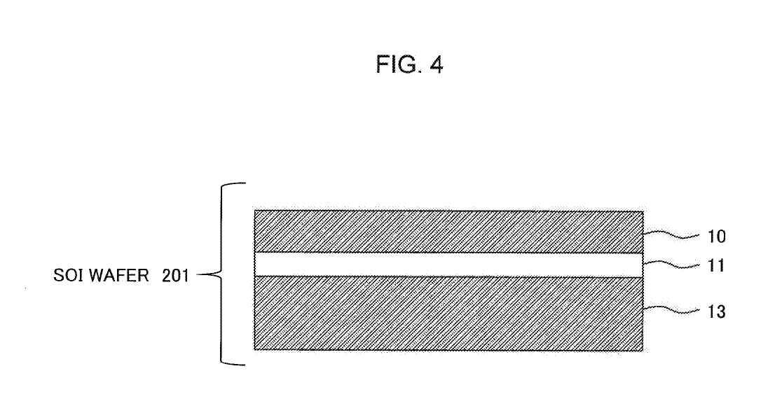

FIG. 3 is a flowchart representing the procedure of manufacturing the optical waveguide element 1 by introducing the impurity into the predetermined region of the Si layer 10 by the method with the ion implantation. FIG. 4 to FIG. 9 are cross-sectional views of a silicon-on-insulator (SOI) wafer 201 in the case of introducing the impurity into the predetermined region of the Si layer 10 by the method with the ion implantation.

First, the SOI wafer 201 is formed (S101: wafer formation) in the method with the ion implantation. FIG. 4 is a cross-sectional view of the SOI wafer 201. As illustrated in FIG. 4, the SOI wafer 201 includes a silicon substrate 13, the SiO₂ layer 11, and the Si layer 10, in which the SiO₂ layer 11 and the Si layer 10 are layered on the silicon substrate 13.

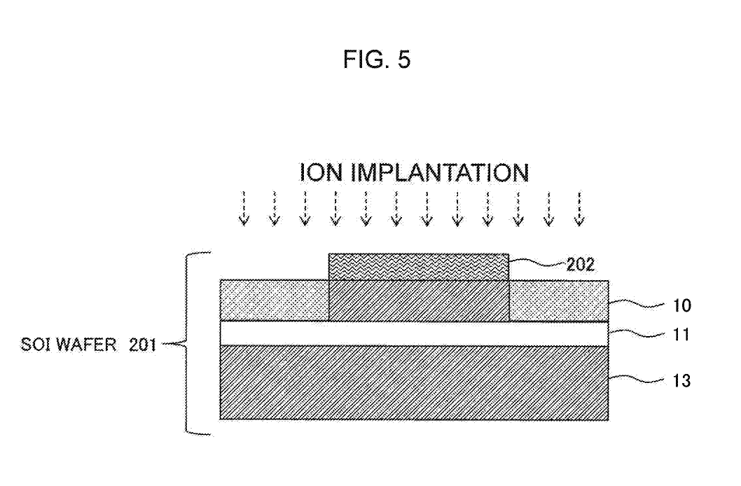

Then, a region other than an ion-implanted region in the Si layer 10 of the SOI wafer 201 is protected with a resist (first resist) (S102: resist patterning). Then, an ion beam is implanted from above the SOI wafer 201 to implant ions into the Si layer 10 (S103: ion implantation). FIG. 5 is a cross-sectional view of the SOI wafer 201 in the case of performing the ion implantation. As illustrated in FIG. 5, the region other than the ion-implanted region in the top surface of the Si layer 10 is protected with a photoresist 202, and ions are implanted from above the SOI wafer 201.

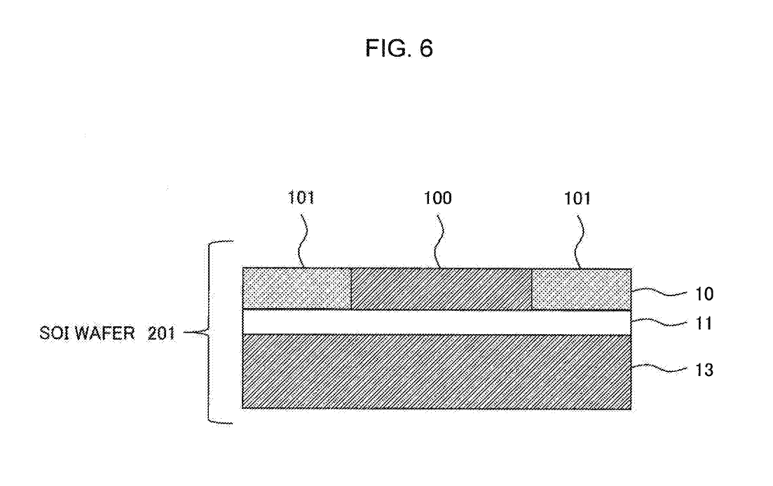

Subsequently, the photoresist 202 placed in step 102 is stripped (S104: resist stripping), and the crystallinity of the Si layer 10 is then recovered (S105: rapid thermal annealing (RTA) (crystallinity recovery)). FIG. 6 is a cross-sectional view of the SOI wafer 201 subjected to the resist stripping. In the SOI wafer 201, a region that is not protected with the photoresist 202 in the Si layer 10 becomes the impurity-implanted region 101 into which ions are implanted.

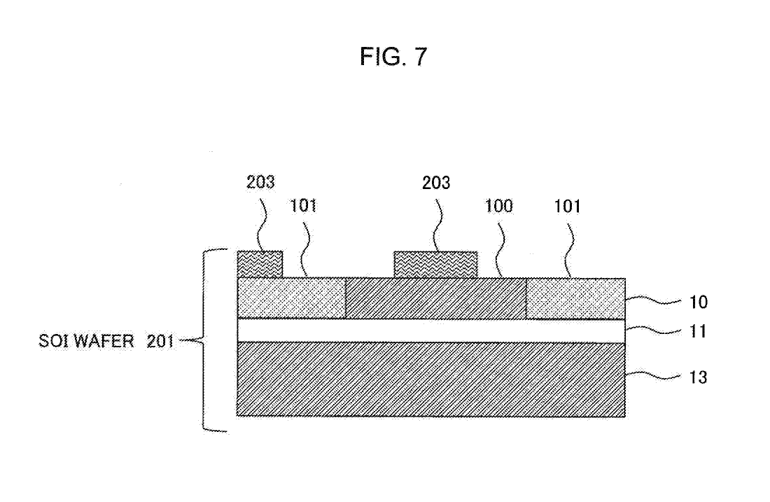

Subsequently, in order to dispose a projection on the Si layer 10, a portion to be the top surface of the projection is protected with a resist 203 (S106: resist mask patterning). FIG. 7 is a cross-sectional view of the SOI wafer 201 subjected to the resist mask patterning. As illustrated in FIG. 7, in the SOI wafer 201, a region corresponding to the top surface of the projection in the region other than the ion-implanted region of the Si layer 10 is protected with the resist 203.

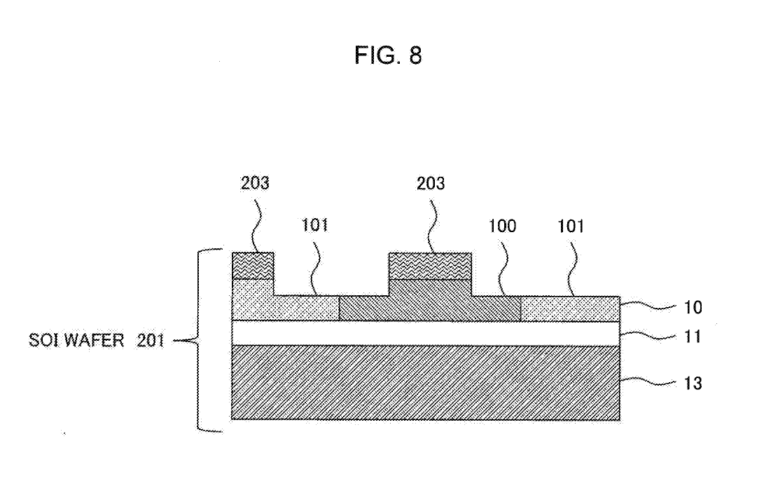

Subsequently, the Si layer 10 in which the resist 203 is placed on the region corresponding to the top surface of the projection is etched to remove a portion corresponding to a predetermined depth in the Si layer 10 (S107: etching). In the Si layer 10, the portion on which the resist 203 is placed in S106 is not etched. FIG. 8 is a cross-sectional view of the SOI wafer 201 subjected to the etching. As illustrated in FIG. 8, the projection is formed on the Si layer 10 of the SOI 201 after the etching.

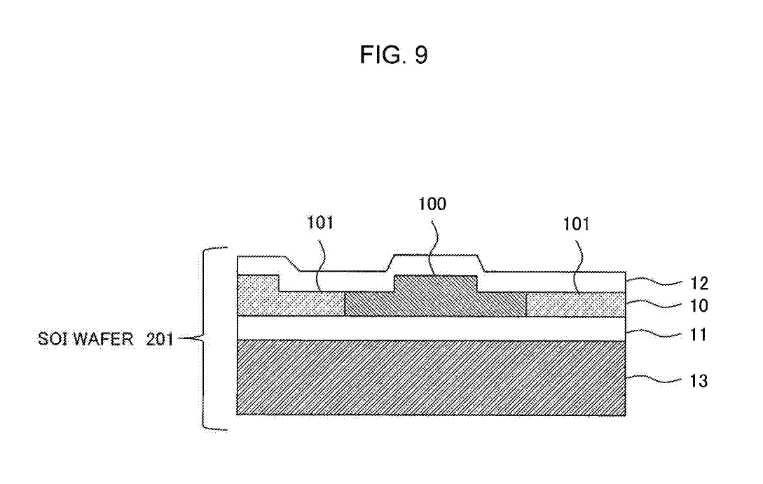

Finally, the resist 203 protected in step 106 is stripped (S108: resist stripping), and the film of the SiO₂ layer 12 is then formed on the top surface of the Si layer 10 (S109: upper layer SiO₂ film formation). FIG. 9 is a cross-sectional view of the SOI wafer 201 after the formation of the film of the SiO₂ layer 12, and the SOI wafer 201 becomes the optical waveguide element 1 illustrated in FIG. 1.

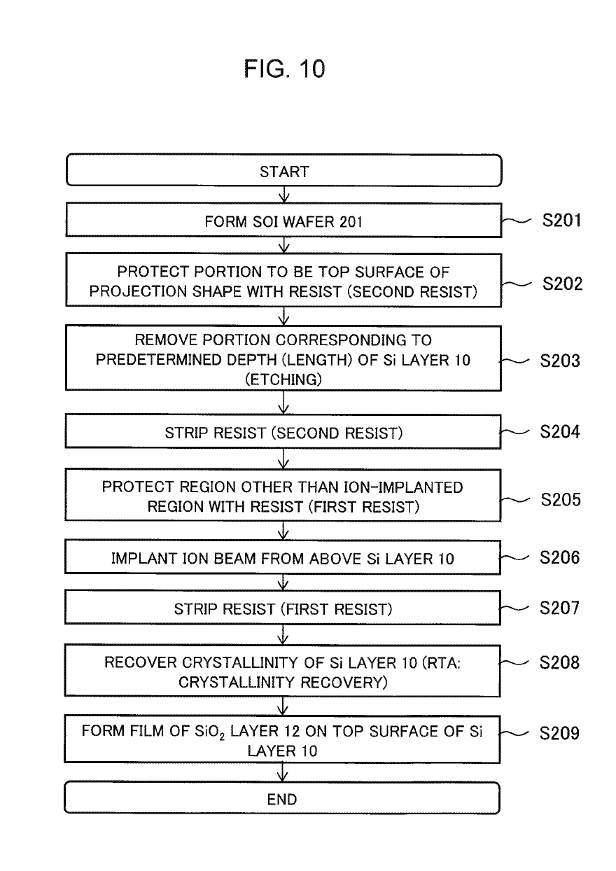

The process represented in FIG. 3 is a process in the case of implanting the impurity into the Si layer 10 in advance, and then forming a rib waveguide. The precision of the resist mask patterning is high because a level difference is absent in the Si layer 10 in the resist mask patterning (S102). However, higher energy than that in the following other process described with reference to FIG. 10 is required when ions are implanted into the Si layer 10.

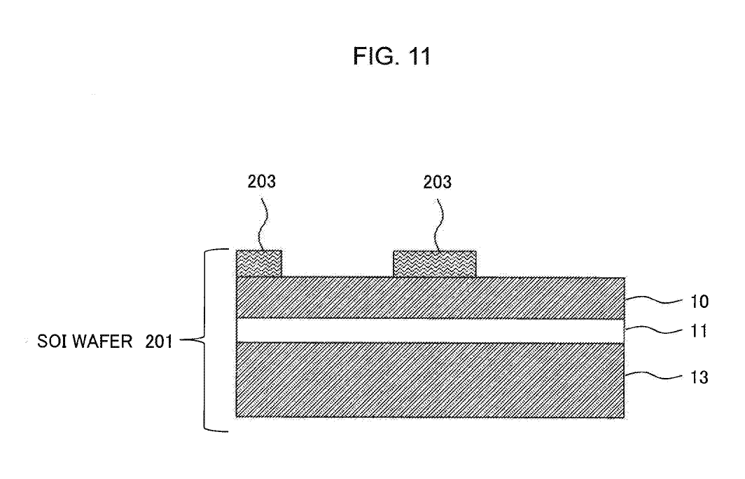

FIG. 10 is a flowchart representing the procedure of introducing the impurity into the predetermined region of the Si layer 10 by the method with the ion implantation to manufacture the optical waveguide element 1. In the process represented in FIG. 10, the rib waveguide (projection shape) is formed in advance, and the impurity is then implanted into the Si layer 10. Further, FIG. 4, FIG. 9, and FIG. 11 to FIG. 14 are cross-sectional views of the silicon-on-insulator (SOI) wafer 201 in the case of introducing the impurity into the predetermined region of the Si layer 10 by the method with the ion implantation.

First, the SOI wafer 201 is formed (S201). The formed SOI wafer is the same as that illustrated in FIG. 4.

Then, in order to dispose a projection on the Si layer 10, a portion to be the top surface of the projection is protected with a resist 203 (S202: resist mask patterning). FIG. 11 is a cross-sectional view of the SOI wafer 201 subjected to the resist mask patterning. As illustrated in FIG. 11, in the Si layer 10 of the SOI wafer 201, a region corresponding to the top surface of the projection is protected with the resist 203.

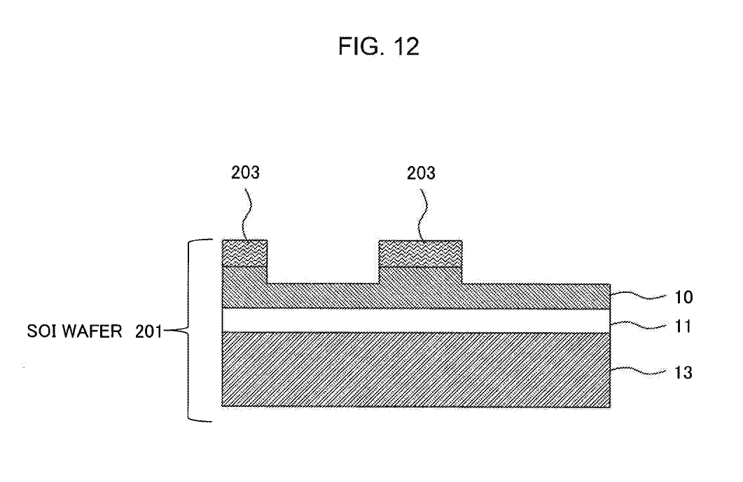

Subsequently, in order to dispose the projection on the Si layer 10, the Si layer 10 is etched to remove a portion corresponding to a predetermined depth (length) in the Si layer 10 (S203: etching). In the Si layer 10, the portion on which the resist 203 is placed in S202 is not etched. FIG. 12 is a cross-sectional view of the SOI wafer 201 subjected to the etching. As illustrated in FIG. 12, the projection is formed on the Si layer 10 of the SOI 201 after the etching. Then, the resist 203 placed in S202 is stripped (S204: resist stripping).

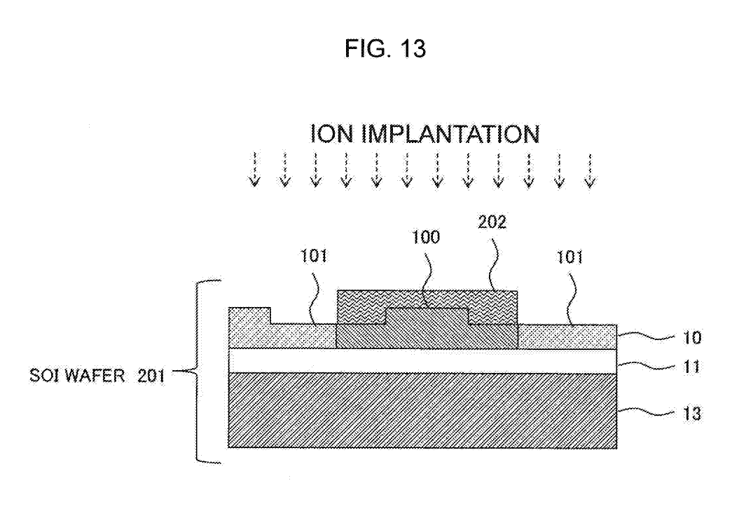

Subsequently, a region other than the ion-implanted region in the Si layer 10 of the SOI wafer 201 is protected with a resist (S205: resist patterning). Then, an ion beam is implanted from above the SOI wafer 201 to implant ions into the Si layer 10 (S206: ion implantation). FIG. 13 is a cross-sectional view of the SOI wafer 201 in the case of performing the ion implantation. As illustrated in FIG. 13, the region other than the ion-implanted region in the top surface of the Si layer 10 is protected with the photoresist 202, and ions are implanted from above the SOI wafer 201.

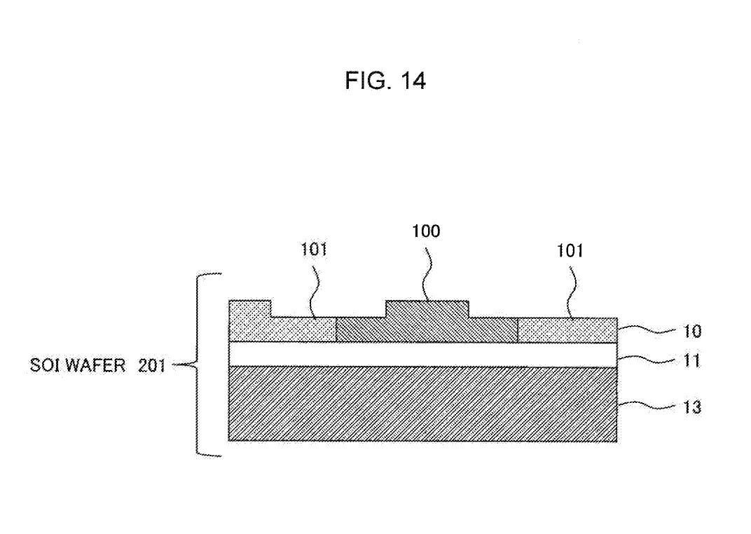

Subsequently, the photoresist 202 placed in step 204 is stripped (S207: resist stripping), and the crystallinity of the Si layer 10 is then recovered (S208: crystallinity recovery (RTA)). FIG. 14 is a cross-sectional view of the SOT wafer 201 subjected to the resist stripping. In the SOI wafer 201, a region that is not protected with the photoresist 202 in the Si layer 10 becomes the impurity-implanted region 101 into which ions are implanted.

Finally, the film of the SiO₂ layer 12 is formed on the top surface of the Si layer 10 (S209: SiO₂ film formation). A cross-sectional view of the SOI wafer 201 after forming the film of the SiO₂ layer 12 in the process in the case of forming a rib waveguide (projection shape) in advance, and then implanting the impurity into the Si layer 10 is the same as that of the optical waveguide element 1 illustrated in FIG. 9.

In the process represented in FIG. 4 and FIG. 9 to FIG. 14, the Si layer 10 is cut in advance in S203, and therefore, energy for implanting ions into the Si layer 10 can be correspondingly reduced. However, a level difference is present in the Si layer 10 in the resist mask patterning (S204), and the precision of the resist mask patterning is reduced.

In the process described above, the crystallinity of the Si layer 10 is deteriorated after the ion implantation; however, since the crystallinity can be restored in a short time using RTA, and the ion implantation is performed in a region other than the optical waveguide, it is not necessary to consider the influence of the silicon crystallinity on propagating light. Further, the performance of the high-temperature diffusion treatment after the ion implantation makes it possible to introduce the impurity into the whole Si layer 10 in the thickness (height) direction of the Si layer 10. Simultaneously with the performance of the high-temperature diffusion treatment, the crystallinity of the Si layer 10 is also recovered.

Light (stray light) propagating through any place other than the core region 100 of the Si layer 10 can be attenuated by free carrier absorption because the optical waveguide element 1 of the second exemplary embodiment of the present invention includes the impurity-implanted region 101 in which the impurity is implanted into the predetermined region of the Si layer 10, as described above. Further, a cost needed for manufacturing the optical waveguide element 1 can be reduced because the impurity-implanted region 101 is formed in the Si layer 10 by directly implanting the impurity into the Si layer 10, in the optical waveguide element 1.

### Third Exemplary Embodiment

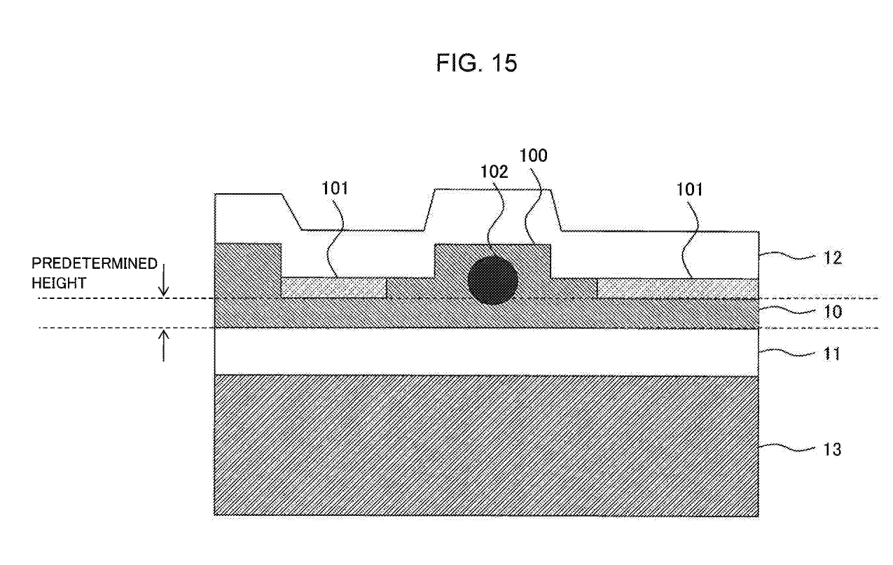

A third exemplary embodiment of the present invention will be described with reference to FIG. 15. FIG. 15 is a cross-sectional view of an SOI wafer 201 according to the third exemplary embodiment of the present invention. Like the optical waveguide elements 1 described in the first and second exemplary embodiments, a Si layer 10 in an optical waveguide element 1 of the third exemplary embodiment of the present invention also includes a ridge optical waveguide as illustrated in FIG. 15.

As illustrated in FIG. 15, an impurity is introduced into a region at a predetermined height from the bottom surface of the Si layer (upper region of Si layer 10, region in vicinity of surface of Si layer 10) in the optical waveguide element 1 of the third exemplary embodiment of the present invention. In an example of FIG. 15, an impurity-implanted region 101 is disposed only in a portion of 0.2 μm (from surface) of an upper portion of a slab region of the Si layer 10.

As described above, optical reflection may occur, and the interference of reflected light with a primary signal results in deterioration of the properties of the primary signal light, because a difference in refractive index occurs in the boundary between a core region 100 and the impurity-implanted region 101 in the Si layer 10.

Thus, the impurity-implanted region 101 is disposed in a region at not less than the predetermined height from the bottom surface of the Si layer 10 (upper region of Si layer 10, region in vicinity of surface of Si layer 10) in the optical waveguide element 1 of the third exemplary embodiment of the present invention. By disposing the impurity-implanted region 101 only in the region at not less than the predetermined height from the bottom surface of the Si layer 10, the area of the boundary between the core region 100 and the impurity-implanted region 101 is reduced to inhibit generation of reflected waves returning to an optical waveguide 102 in the core region 100.

Because light (stray light) propagating into a slab waveguide is strongly confined, and exists in a region (slab region) other than the core region 100, the stray light can be eliminated even when the impurity-implanted region 101 is in the upper portion (surface portion) of the slab region.

In the case of implanting the impurity only into the upper portion of the slab region, the more amount of the implanted impurity than that in a case in which the whole slab region is the impurity-implanted region 101 enables stray light to be efficiently eliminated.

In the case of implanting the impurity only into the upper part (surface) of the slab region of the Si layer 10, a manufacturing cost can be reduced due to, e.g., possible reduction in energy for implanting an ion beam, and the elimination of the need of high-temperature diffusion, in a method with ion implantation.

As described above, generation of reflected light interfering with primary signal light propagating through the optical waveguide 102 can be inhibited because the impurity is implanted only into the upper portion of the slab region, in the optical waveguide element 1 of the third exemplary embodiment of the present invention.

### Fourth Exemplary Embodiment

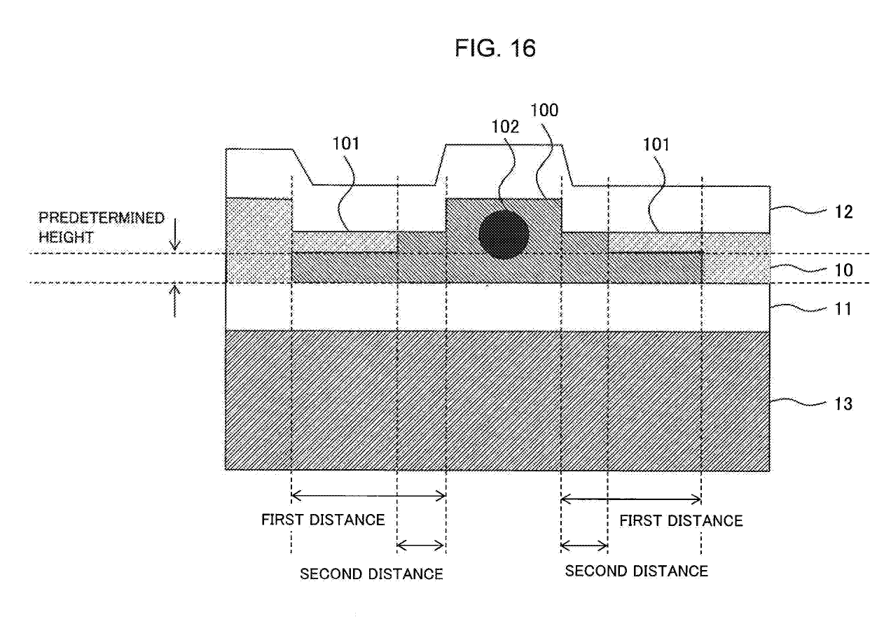

A fourth exemplary embodiment of the present invention will be described with reference to FIG. 16. FIG. 16 is a cross-sectional view of an SOI wafer 201 according to the fourth exemplary embodiment of the present invention. As illustrated in FIG. 16, a Si layer 10 in an optical waveguide element 1 of the fourth exemplary embodiment of the present invention also includes a ridge optical waveguide.

As illustrated in FIG. 16, the fourth exemplary embodiment of the present invention is an exemplary embodiment in which the second exemplary embodiment and the third exemplary embodiment described above are combined. In the optical waveguide element 1 according to the fourth exemplary embodiment of the present invention, (1) an impurity-implanted region 101 is disposed in a region at not less than a second distance from a side of a projection. In the optical waveguide element 1, (2) the impurity-implanted region 101 is placed only in a region at not less than a predetermined height from the bottom surface of the silicon layer in a region at not more than a first distance that is longer than the second distance from the side of the projection.

As described above, an impurity is introduced into a region at a predetermined height from the bottom surface of the Si layer 10 (upper region of Si layer 10, region in vicinity of surface of Si layer 10) in a region (region at not less than second distance shorter than first distance) in the vicinity of a core region 100 in a slab region. Therefore, in the optical waveguide element 1, the area of the boundary between the core region 100 and the impurity-implanted region 101 can be reduced to inhibit generation of reflected waves returning to an optical waveguide 102 in the core region 100.

The impurity is introduced into the whole Si layer 10 in a region apart from the core region 100 in the slab region. The rate of the attenuation of stray light due to the impurity-implanted region 101 becomes high because the impurity is implanted into the whole Si layer 10. However, since the boundary between the core region 100 and the impurity-implanted region 101 is at not less than a predetermined distance (first distance) from the core region 100, the influence of reflected light on primary signal light is reduced.

The configuration of the optical waveguide element 1 as described above can be actualized by changing energy for implanting an ion beam in a method with ion implantation. In the Si layer 10, energy for implanting an ion beam is reduced in a region in the vicinity of the core region 100 in comparison with a region apart from the core region 100.

As described above, in the optical waveguide element 1 of the fourth exemplary embodiment of the present invention, the generation of reflected waves can be inhibited in the region in the vicinity of the core region 100, and the influence of reflected light on primary signal light can be reduced while reliably eliminating stray light in the region apart from the core region 100.

### Fifth Exemplary Embodiment

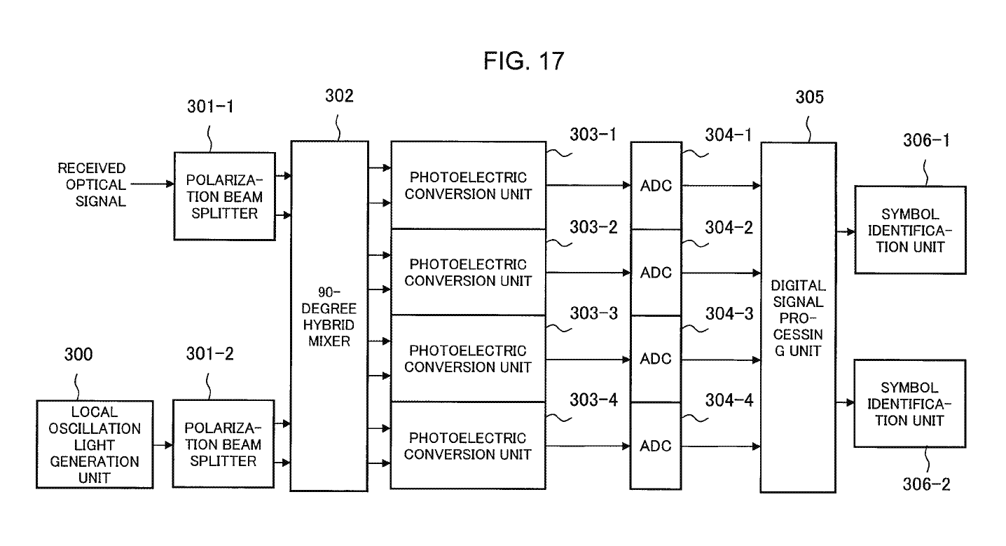

A fifth exemplary embodiment of the present invention will be described with reference to FIG. 17.

The fifth exemplary embodiment of the present invention is an exemplary embodiment in which the optical waveguide elements 1 are applied to a coherent mixer. The coherent mixer can be downsized by forming the coherent mixer using silicon. However, silicon, which has a low optical attenuance, causes the problem of an increased possibility that stray light propagates through the silicon and affects primary signal light. Thus, the optical waveguide elements 1 of the first to fourth exemplary embodiments of the present invention are applied to the coherent mixer in order to solve the problem. As a result, stray light propagating in the coherent mixer is attenuated to inhibit the stray light from affecting primary signal light.

The coherent mixer according to the fifth exemplary embodiment of the present invention can be applied to, for example, a 90-degree hybrid mixer in an optical receiver using a digital coherent system described below, but is not limited to the application to the 90-degree hybrid mixer.

In the optical digital coherent system, high-speed optical transmission is actualized by allowing a phase modulated signal to propagate with two orthogonal polarized waves. In the optical digital coherent system, a side receiving an optical signal allows local light to interfere with a received phase modulated signal to output plural (e.g., eight) optical signals, and the output optical signals are converted into electric signals. The electric signals are further converted into digital signals, which are then subjected to demodulation processing in a digital signal processing unit to restore bit strings.

FIG. 17 is a block diagram illustrating a configuration example of the optical receiver using the digital coherent system. First, a received optical signal and local oscillation light that is sent by a local oscillation light generation unit 300 and has the same frequency band as the received optical signal are input into a polarization beam splitter 301. The local oscillation light generation unit 300 sends local oscillation light having a preset frequency.

The polarization beam splitter 301 splits the received optical signal and the local oscillation light into signal components (X-polarized wave signals) that are parallel to a polarization axis, and signal components (Y-polarized wave signals) that are orthogonal to the polarization axis. For example, the frequency value of the optical signal in a sending side and the frequency value of the local oscillation light in a receiving side are determined in advance by an administrator, and the frequencies are set for corresponding light sources.

Then, the received optical signal in combination with the local oscillation light is input into a 90-degree hybrid mixer 302 referred to as a coherent mixer. Eight optical signals output from the 90-degree hybrid mixer 302 are converted into electric signals by photoelectric conversion units 303-1 to 303-4, and the electric signals are further converted from analog signals into digital signals by AD converters (analog-to-digital converters (ADCs)) 304-1 to 304-4.

The four digital signals generated in such a manner are signals corresponding to the real and imaginary parts of the signal components (X-polarized wave signals) that are parallel to the polarization axis of the 90-degree hybrid mixer 302, and the real and imaginary parts of the signal components (Y-polarized wave signals) that are orthogonal to the polarization axis of the 90-degree hybrid mixer 302, in the received optical signal. The digital signals generated by the ADCs 304-1 to 304-4 are subjected to demodulation processing by a digital signal processing unit 305, and then, bit strings are finally restored by symbol identification units 306-1 and 306-2.

As described above, it is necessary that in the optical digital coherent system, the side receiving an optical signal includes the 90-degree hybrid mixer 302 referred to as a coherent mixer that allows a received phase modulated signal and an optical signal (local oscillator signal) from the local oscillation light generation unit 300 to interfere with each other. It is necessary that in the 90-degree hybrid mixer 302, the deterioration of the properties of a plurality of output optical signals is inhibited in order to suppress an error in the case of signal demodulation in the digital signal processing unit 305. In other words, it is necessary that in the 90-degree hybrid mixer 302, the interference of stray light with primary signal light and the deterioration of the properties of the primary signal light are inhibited.

Thus, in the fifth exemplary embodiment of the present invention, an impurity-implanted region 101 is disposed in a predetermined region to reliably attenuate stray light and to inhibit the deterioration of the properties of primary signal light, in the 90-degree hybrid mixer 302.

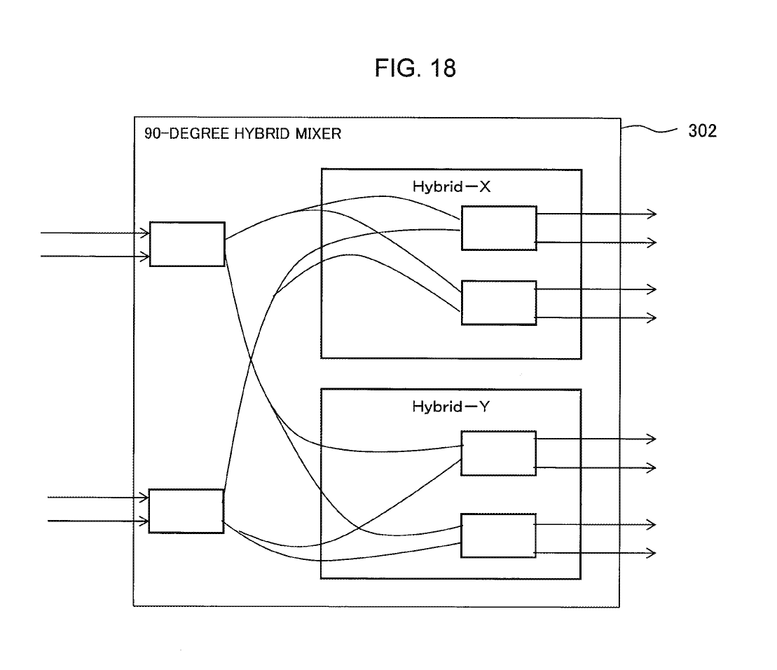

FIG. 18 is a view illustrating a configuration example of the 90-degree hybrid mixer 302 according to the fifth exemplary embodiment of the present invention. FIG. 18 illustrates the configuration example of the 90-degree hybrid mixer 302 in the case of allowing a received optical signal and local light to interfere with each other to obtain eight optical output signals. In the 90-degree hybrid mixer 302, an impurity is implanted into a region other than a core region 100 through which primary signal light propagates, and the impurity-implanted region 101 is disposed. In other words, in the 90-degree hybrid mixer 302, the impurity is implanted into the region other than the core region 100 in which an optical waveguide for a received optical signal, an optical waveguide for local light, a place in which a received optical signal and local light interfere with each other, and an optical waveguide for interfering light exist. Because the impurity-implanted region 101 attenuates stray light propagating in the 90-degree hybrid mixer 302, and suppresses the influence of the stray light on a received optical signal, local light, and interfering light, the deterioration of the properties of optical output signals is inhibited.

As described above, in the fifth exemplary embodiment of the present invention, the deterioration of the properties of optical output signals can be inhibited because stray light is attenuated with a predetermined region in the 90-degree hybrid mixer 302 referred to as a coherent mixer, as the impurity-implanted region 101.

### Sixth Exemplary Embodiment

A sixth exemplary embodiment of the present invention is an exemplary embodiment in which the optical waveguide elements 1 are applied to a polarization beam splitter.

The polarization beam splitter according to the sixth exemplary embodiment of the present invention can be applied to, for example, the polarization beam splitter 301 (PBS) in the optical receiver using the digital coherent system illustrated in FIG. 17, but is not limited to the application. A configuration example of an optical receiver using a digital coherent system according to the sixth exemplary embodiment of the present invention is similar to that in the sixth exemplary embodiment of the present invention illustrated in FIG. 17.

A polarization beam splitter 301 can be downsized by forming the polarization beam splitter 301 using silicon. However, silicon, which has a low optical attenuance, causes the problem of an increased possibility that stray light propagates through the silicon and affects primary signal light. Thus, in order to solve the problem, the optical waveguide elements 1 of the first to fourth exemplary embodiments of the present invention are applied to the polarization beam splitter 301 to attenuate stray light propagating in the polarization beam splitter 301, thereby inhibiting the stray light from affecting primary signal light.

In an optical digital coherent system, before a received optical signal and local light are input into a 90-degree hybrid mixer 302, each light is input into the polarization beam splitter 301 which splits each light into an X-polarized wave signal and a Y-polarized wave signal, as described in the fifth exemplary embodiment of the present invention.

As described above, it is necessary that in the digital coherent system, the deterioration of the properties of a plurality of output optical signals is inhibited in order to suppress an error in the case of signal demodulation in a digital signal processing unit 305. Accordingly, it is also necessary that in the polarization beam splitter 301, the interference of stray light with primary signal light and the deterioration of the properties of the primary signal light are inhibited, similarly in the 90-degree hybrid mixer 302.

Thus, in the sixth exemplary embodiment of the present invention, an impurity-implanted region 101 is also disposed in the polarization beam splitter 301 to reliably attenuate stray light and to inhibit the deterioration of the properties of primary signal light.

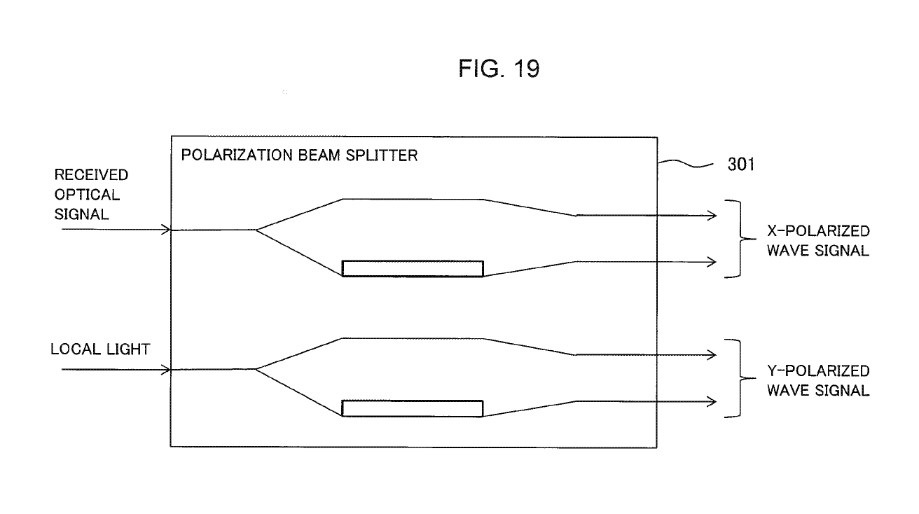

FIG. 19 is a view illustrating a configuration example of the polarization beam splitter 301 according to the sixth exemplary embodiment of the present invention. The polarization beam splitter 301 splits an input optical signal into signal components (X-polarized wave signals) that are parallel to the polarization axis, and signal components (Y-polarized wave signals) that are orthogonal to the polarizing axis.

In the polarization beam splitter 301, an impurity is implanted into a region other than a core region in which a waveguide for an input optical signal exists, and a region other than a core region in which a waveguide for optical output signals subjected to polarization splitting exists, and the impurity-implanted region 101 is disposed. The impurity-implanted region 101 attenuates reflected light and scattered light (stray light) generated in the polarization beam splitter 301, and suppresses the influence of the stray light on primary signal light.

As described above, in the sixth exemplary embodiment of the present invention, the deterioration of the properties of optical output signals can be inhibited because stray light is attenuated with a predetermined region in the polarization beam splitter 301, as the impurity-implanted region 101.

### Seventh Exemplary Embodiment

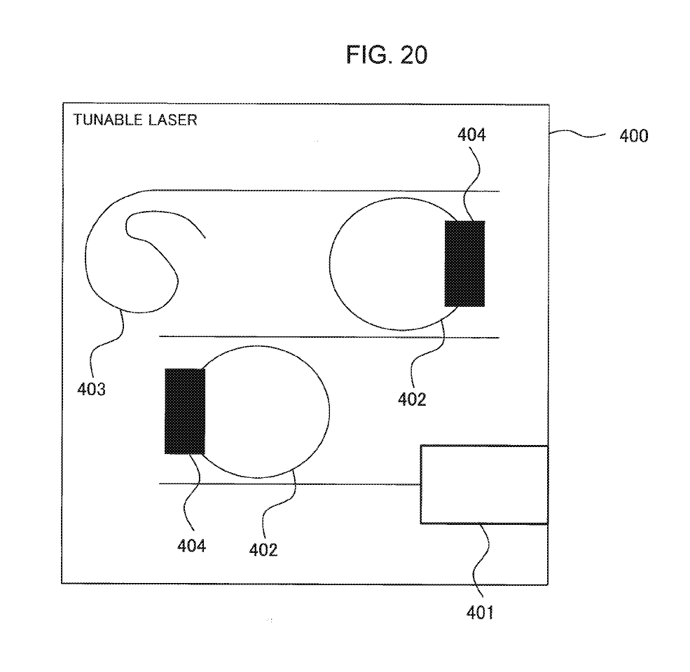

A seventh exemplary embodiment of the present invention will be described with reference to FIG. 20.

The seventh exemplary embodiment of the present invention is an exemplary embodiment in which the optical waveguide elements 1 are applied to a tunable laser (wavelength-variable laser).

A tunable laser can be downsized by forming the tunable laser using silicon. However, silicon, which has a low optical attenuance, causes the problem of an increased possibility that stray light propagates through the silicon and affects primary signal light.

Further, there is a problem that the tunable laser is prone to generate stray light because the length of an optical waveguide in a ring resonator that varies the wavelength of light becomes long.

Furthermore, there is also a problem that the tunable laser is prone to generate stray light because of many coupling points between an optical waveguide through which primary signal light propagates and another element such as a loop mirror, and of many reflection points.

Thus, in order to solve the problems, the optical waveguide elements 1 of the first to fourth exemplary embodiments of the present invention are applied to the tunable laser to attenuate stray light propagating in the tunable laser, thereby inhibiting the stray light from affecting primary signal light.

The tunable laser according to the seventh exemplary embodiment of the present invention can be applied to, for example, the local oscillation light generation unit 300 in the optical receiver using the digital coherent system illustrated in FIG. 17, but is not limited to the application.

FIG. 20 illustrates a configuration example of a tunable laser 400 utilizing a ring resonator. As illustrated in FIG. 20, the tunable laser 400 includes a semiconductor optical amplifier (SOA) 401, a ring resonator 402, and a loop mirror 403.

In the tunable laser 400, light output from the SOA 401 is input into the ring resonator 402, is reflected off the loop mirror 403 in a terminal, returns to the SOA 401, and is output. In such a case, current is passed to a heater 404 mounted on the ring resonator 402 to change the temperature of a ring waveguide and to change an effective refractive index, thereby tuning output light to a desired wavelength.

In the tunable laser 400 described above, the distance of the ring waveguide in the ring resonator 402 is long, and there are many places in which reflected light and scattered light are generated. Therefore, primary signal light propagating through the ring waveguide is susceptible to the influence (interference) of the reflected light and the scattered light.

Thus, in the seventh exemplary embodiment of the present invention, an impurity is implanted into a predetermined region in the tunable laser 400, stray light such as reflected light or scattered light is reliably attenuated by an impurity-implanted region 101, and the deterioration of the properties of primary signal light is inhibited.

In the tunable laser 400, the impurity is implanted into a region other than a core region 100 in which the ring waveguide exists, and the impurity-implanted region 101 is disposed. The impurity-implanted region 101 attenuates reflected light and scattered light (stray light) generated in the tunable laser 400, and the influence of the stray light on primary signal light is suppressed.

As described above, in the seventh exemplary embodiment of the present invention, the deterioration of the properties of optical output signals can be inhibited because stray light is attenuated by allowing the predetermined region (the region other than the region in which the ring waveguide exists) in the tunable laser 400 to be the impurity-implanted region 101.

Some or all of the exemplary embodiments described above can be described as the following supplementary notes, but are not limited to the following.

[Supplementary Note 1]

An optical waveguide element, including a ridge optical waveguide formed in a silicon layer,

wherein an impurity-implanted region in which an impurity that forms an electron or a hole is implanted into the silicon layer is disposed in a region at not less than a predetermined distance from the ridge optical waveguide in the silicon layer.

[Supplementary Note 2]

The optical waveguide element according to Supplementary Note 1, wherein a portion at not less than a predetermined height from a bottom surface of the silicon layer is allowed to be the impurity-implanted region.

[Supplementary Note 3]

The optical waveguide element according to any one of Supplementary Notes 1 and 2, wherein a region at not less than a first distance from the ridge optical waveguide, and a region that is at not less than a second distance that is shorter than the first distance from the ridge optical waveguide, and at not less than a predetermined height from a bottom surface of the silicon layer are allowed to be the impurity-implanted region.

[Supplementary Note 4]

The optical waveguide element according to any one of Supplementary Notes 1 to 3, wherein the impurity is phosphorus or boron.

[Supplementary Note 5]

The optical waveguide element according to any one of Supplementary Notes 1 to 4, wherein a silicon-dioxide layer is disposed above and below the silicon layer.

[Supplementary Note 6]

A Coherent Mixer, Including:

the optical waveguide element according to any one of Supplementary Notes 1 to 5; and

an interference unit that allows an input optical signal that is input and local light oscillated by a local oscillation light generation unit to interfere with each other, and outputs a plurality of output optical signals,

wherein the optical waveguide element transmits the input optical signal, the local light, and the plurality of output optical signals.

[Supplementary Note 7]

A polarization beam splitter, including:

the optical waveguide element according to any one of Supplementary Notes 1 to 5; and

a splitting unit that splits an input optical signal that is input, into a first optical signal that is a signal component that is parallel to a change axis, and a second optical signal that is a signal component that is orthogonal to the change axis,

wherein the optical waveguide element transmits the input optical signal and the first and second optical signals.

[Supplementary Note 8]

A tunable laser, including:

a ring resonator including the optical waveguide element according to any one of Supplementary Notes 1 to 5;

a semiconductor optical amplifier that outputs an optical signal; and

a loop mirror that reflects an input optical signal,

wherein the ring resonator changes the optical signal output by the semiconductor optical amplifier into a predetermined wavelength;

the loop mirror reflects and returns the optical signal input from the optical waveguide element included in the ring resonator, to the optical waveguide element; and

the semiconductor optical amplifier outputs, to outside, the optical signal reflected by the loop mirror and transmitted through the optical waveguide element.

[Supplementary Note 9]

A method for manufacturing an optical waveguide element, including:

protecting, with a first resist, a top surface of a region other than a region into which an impurity is implanted, in a silicon layer;

implanting an impurity that forms an electron or a hole into the silicon layer from above a top surface of the silicon layer protected with the first resist;

stripping the first resist after implanting the impurity;

protecting, with a second resist, a region corresponding to a top surface of a ridge optical waveguide in the silicon layer after stripping the first resist;

removing a portion having a predetermined depth from the top surface of the silicon layer in a region other than the region protected with the second resist in the silicon layer protected with the second resist; and

stripping the second resist after removing the portion having the predetermined depth.

[Supplementary Note 10]

A method for manufacturing an optical waveguide element, including:

protecting, with a second resist, a region corresponding to a top surface of a ridge optical waveguide in a silicon layer;

removing a portion having a predetermined depth from a top surface of the silicon layer in a region other than the region protected with the second resist in the silicon layer protected with the second resist;

stripping the second resist after removing the portion having the predetermined depth;

protecting, with a first resist, a top surface of a region other than a region in which an impurity that forms an electron or a hole is implanted into the silicon layer, in the silicon layer after stripping the second resist;

implanting an impurity from above a top surface of the silicon layer protected with the first resist; and

stripping the first resist after implanting the impurity.

[Supplementary Note 11]

The method for manufacturing an optical waveguide element according to Supplementary Note 9 or Supplementary Note 10, wherein a region protected with the first resist is a region at not more than a predetermined distance from a position corresponding to a side of the ridge optical waveguide.

[Supplementary Note 12]

The method for manufacturing an optical waveguide element according to any one of Supplementary Notes 9 to 11, wherein the impurity is implanted into a portion at not less than a predetermined height from a bottom surface of the silicon layer.

[Supplementary Note 13]

The method for manufacturing an optical waveguide element according to any one of Supplementary Notes 9 to 12, wherein the impurity is implanted into a portion at not less than a predetermined height from a bottom surface of the silicon layer in a region into which the impurity is implanted, and which is at not more than a predetermined distance from a position corresponding to a side of the ridge optical waveguide.

[Supplementary Note 14]

The method for manufacturing an optical waveguide element according to any one of Supplementary Notes 9 to 13, wherein the impurity is phosphorus or boron.

[Supplementary Note 15]

The method for manufacturing an optical waveguide element according to any one of Supplementary Notes 9 to 14, wherein a silicon-dioxide layer is disposed above and below the silicon layer.

The present invention is not limited to the exemplary embodiments described above, and any design modifications and the like without departing from the gist of this invention are encompassed by this invention. This application claims priority based on Japanese Patent Application No. 2013-267193, which was filed on Dec. 25, 2013, and of which the entire disclosure is incorporated herein.

### INDUSTRIAL APPLICABILITY

The optical waveguide element according to the present invention can be applied widely to an optical component, which is manufactured utilizing CMOS process technology, and in which a silicon optical waveguide is placed.

### REFERENCE SIGNS LIST

10 Si layer
11, 12 SiO₂ layer
13 Silicon substrate
100 Core region
101 Impurity-implanted region
102 Optical waveguide
201 SOI wafer
202 Resist
203 Resist
300 Local oscillation light generation unit
301, 301-1, 301-2 Polarization beam splitter
302 90-degree hybrid mixer
303 Photoelectric conversion unit
304 ADC
305 Digital signal processing unit
306 Symbol identification unit
400 Tunable laser
401 SOA
402 Ring resonator
403 Loop mirror
404 Heater

1. An optical waveguide element, comprising a silicon layer and silicon-dioxide layers placed above and below the silicon layer,
wherein the silicon layer comprises a ridge optical waveguide and an impurity-implanted region placed at not less than a predetermined distance from the ridge optical waveguide.

2. The optical waveguide element according to claim 1, wherein the impurity-implanted region is a region in which an impurity that forms an electron or a hole is implanted into the silicon layer.

3. The optical waveguide element according to claim 2, wherein the impurity is phosphorus or boron.

4. The optical waveguide element according to claim 1, wherein a portion at not less than a predetermined height from a bottom surface of the silicon layer is the impurity-implanted region.

5. The optical waveguide element according to claim 1, wherein a region at not less than a first distance from the ridge optical waveguide, and a region that is at not less than a second distance that is shorter than the first distance from the ridge optical waveguide, and at not less than a predetermined height from a bottom surface of the silicon layer are allowed to be the impurity-implanted region.

6. A coherent mixer, comprising:
the optical waveguide element according to claim 1; and
an interference unit that allows an input optical signal that is input and local light oscillated by a local oscillation light generation unit to interfere with each other, and outputs a plurality of output optical signals,
wherein the optical waveguide element transmits the input optical signal, the local light, and the plurality of output optical signals.

7. A polarization beam splitter, comprising:
the optical waveguide element according to claim 1; and
a splitting unit that splits an input optical signal that is input, into a first optical signal that is a signal component that is parallel to a polarization axis, and a second optical signal that is a signal component that is orthogonal to the polarization axis,
wherein the optical waveguide element transmits the input optical signal and the first and second optical signals.

8. A tunable laser, comprising:
a ring resonator comprising the optical waveguide element according to claim 1;
a semiconductor optical amplifier that outputs an optical signal; and
a loop mirror that reflects an input optical signal,
wherein the ring resonator changes the optical signal output by the semiconductor optical amplifier into a predetermined wavelength;
the loop mirror reflects and returns the optical signal input from the optical waveguide element comprised in the ring resonator, to the optical waveguide element; and
the semiconductor optical amplifier outputs, to outside, the optical signal reflected by the loop mirror and transmitted through the optical waveguide element.

9. A method for manufacturing an optical waveguide element, comprising:
placing a silicon layer on a top surface of a silicon-dioxide layer;
placing a first resist on a top surface of a region other than a region into which an impurity is implanted in the silicon layer;
implanting an impurity that forms an electron or a hole from above the first resist and the silicon layer;
striping the first resist after implanting the impurity;
placing a second resist on a region corresponding to a top surface of a ridge optical waveguide in the silicon layer after stripping the first resist;
subjecting a predetermined region comprising the second resist of the silicon layer to etching;
stripping the second resist after the etching; and
placing another silicon-dioxide layer on a top surface of a silicon layer from which the second resist is stripped.

10. A method for manufacturing an optical waveguide element, comprising:
placing a silicon layer on a top surface of a silicon-dioxide layer;
placing a second resist on a region corresponding to a top surface of a projection comprising a ridge optical waveguide in the silicon layer;
subjecting a predetermined region comprising the second resist of the silicon layer to etching;
stripping the second resist after the etching;
placing a first resist on a top surface of a region other than a region into which an impurity is implanted in the silicon layer after stripping the second resist;
implanting an impurity that forms an electron or a hole from above the first resist and the silicon layer;
stripping the first resist after implanting the impurity; and
placing another silicon-dioxide layer on a top surface of a silicon layer from which the first resist is stripped.

11. The method for manufacturing an optical waveguide element according to claim 9, wherein a region protected with the first resist is a region at not more than a predetermined distance from a position corresponding to a side of the ridge optical waveguide.

12. The method for manufacturing an optical waveguide element according to claim 9, wherein the impurity is implanted into a portion at not less than a predetermined height from a bottom surface of the silicon layer.

13. The method for manufacturing an optical waveguide element according to claim 9, wherein the impurity is implanted into a portion at not less than a predetermined height from a bottom surface of the silicon layer in a region into which the impurity is implanted, and which is at not more than a predetermined distance from a position corresponding to a side of the ridge optical waveguide.

14. The method for manufacturing an optical waveguide element according to claim 10, wherein a region protected with the first resist is a region at not more than a predetermined distance from a position corresponding to a side of the ridge optical waveguide.

15. The method for manufacturing an optical waveguide element according to claim 10, wherein the impurity is implanted into a portion at not less than a predetermined height from a bottom surface of the silicon layer.

16. The method for manufacturing an optical waveguide element according to claim 10, wherein the impurity is implanted into a portion at not less than a predetermined height from a bottom surface of the silicon layer in a region into which the impurity is implanted, and which is at not more than a predetermined distance from a position corresponding to a side of the ridge optical waveguide.
